(19) United States
(12) Patent Application Publication
(10) Pub. No.: US 2012/0025732 A1
(43) Pub. Date: Feb. 2, 2012

(54) LIGHT EMITTING DEVICE AND METHOD FOR DRIVING THE SAME

(75) Inventor: Atsushi Hamaguchi, Yokohama-shi (JP)

(73) Assignee: CANON KABUSHIKI KAISHA, Tokyo (JP)

(21) Appl. No.: 13/190,349

(22) Filed: Jul. 25, 2011

(30) Foreign Application Priority Data
Jul. 28, 2010 (JP) 2010-169701

(51) Int. Cl. H05B 37/02; H01L 27/32

(52) U.S. Cl. 315/250; 257/40; 257/E27.119

(57) ABSTRACT

A light emitting device contains organic EL elements of different colors and outputs light emitted from the organic EL elements, in which, when outputting white light, the organic EL element, in which the luminance when light is emitted at a current density at which a luminous efficiency reaches a maximum is lower than that of the organic EL elements of the other colors, among the organic EL elements of different colors emits light with a current having a current density higher than the current density at which the luminous efficiency reaches the maximum and a highest duty among the organic EL elements of different colors, and the organic EL elements of the remaining colors emit light with a current having the current density at which the luminous efficiency reaches the maximum and at a duty lower than the duty.

### BACKGROUND OF THE INVENTION

1. Field of the Invention

The present invention relates to a method for driving a light emitting device, such as a self-emitting display device or a lighting device, and, in detail, relates to a light emitting device employing an organic EL element and a method for driving the same.

2. Description of the Related Art

An organic electroluminescence (EL) display device employs an organic EL element as a light emitting element. The organic EL element has a structure in which a thin film containing an organic compound is sandwiched between an anode and a cathode. When a current is caused to flow, holes and electrons are injected from the anode and the cathode and are combined within an organic compound layer to form excitons. When the excitons return to a ground state, light is emitted. The organic EL display device has high contrast and is easy to reduce the thickness, and thus has drawn attention as a major candidate for a flat panel display. Moreover, the response rate to liquid crystal displays is very high and thus the organic EL display device is suitable also for movie display. With respect to pixels, by structuring organic EL elements having 3 colors, namely red (R), green (G), and blue (B), as sub-pixels, color display can be achieved.

The organic EL display device is a self-emitting type and thus can switch light ON or OFF for each light emitting element, which produces a possibility that the power consumption can be made lower than that of liquid crystal display devices requiring a back light on the entire surface. It has been desired to increase the luminous efficiency of each organic EL element and reduce the power consumption as the whole display device to the minimum level.

U.S. Pat. No. 7,301,511, Specification, discloses the invention that reduces power consumption by causing organic EL elements of the respective colors to operate at a current density which gives the maximum luminous efficiency.

Japanese Patent Laid-Open No. 2004-265755 discloses the invention that suppresses degradation of a blue organic EL element containing a phosphorescent material, which easily deteriorates, to the minimum level by uniformly setting the current density of each of the organic EL elements of RGB to a value at which the blue luminous efficiency reaches the maximum.

A reduction in the luminous efficiency at a current density higher than the maximum value is remarkable particularly in the organic EL element employing phosphorescent materials. It is said that this phenomenon is caused by the fact that the energy movement from a host to a luminescent dopant becomes difficult to occur due to the collision of the triplet excitons referred to as T-T annihilation. Originally, the organic EL element using phosphorescent materials utilizes light emission from the triplet excitons and thus is expected to have high luminous efficiency. However, due to this phenomenon, the peak of the luminous efficiency appears at a relatively low current density and the luminous efficiency at the peak is not always high.

In a display device in which organic EL elements of phosphorescent light emission and fluorescent light emission of different colors are mixed, when light of each color is emitted at a current density at which the luminous efficiency reaches the maximum, the luminance of the organic EL element of phosphorescent light emission is exceptionally lower than the luminance of the organic EL element of fluorescent light emission. Also when phosphorescent light emission and fluorescent light emission are not mixed, the relationship between the luminous efficiency and the current density is usually greatly different among organic EL elements of different colors. When pixels are constituted with such organic EL elements and light of each color is emitted at the current density at which the luminous efficiency reaches the maximum in order to output white light, the luminance of each color is greatly different from each other.

In order to achieve standard white light, light with favorable white balance, i.e., light with a given luminance ratio, needs to achieve. Moreover, the total luminance needs to be set to a value defined as the standard of a display device. When the organic EL element of each color is driven at the current density which gives the maximum luminous efficiency, white light of a given luminance with favorable white balance cannot be obtained.

However, when the current density is set to a value deviating from the maximum luminous efficiency in order to adjust the luminance of each color, an increase in power consumption is caused. A lighting device that obtains white light synthesized by arranging light emitting elements of RGB in parallel also has the same problem.

### SUMMARY OF THE INVENTION

According to an aspect of the present invention, a method is provided that obtains output having a given brightness and favorable white balance while reducing power consumption to a low level.

According to another aspect of the present invention, a light emitting device comprises organic EL elements of different colors and outputs light emitted from the organic EL elements,

wherein

the luminance of the organic EL element of one color is lower than that of the organic EL elements of the other colors when each of the organic EL elements of different colors emits light by a supplied current of a current density at which a luminous efficiency reaches a maximum,

and

when the light emitting device outputs white light, the organic EL element of the one color emits light by a supplied current of a current density higher than the current density at which the luminous efficiency reaches the maximum at a highest duty among the organic EL elements of different colors, and the organic EL elements of the other colors emit light by supplied currents of the current density at which the luminous efficiency reaches the maximum.

According to another aspect of the present invention, the organic EL element of a color with the lowest luminance when light is emitted at the current density which gives the maximum luminous efficiency is made to emit light at a current density higher than the current density at which the luminous efficiency reaches the maximum and a duty higher than that of the other colors. With respect to the organic EL elements of the other colors, light is emitted at the current density at which the luminous efficiency reaches the maximum and the duty is made small to adjust the white balance. As a result, the increase in power consumption of the organic EL element that emits light at a current density higher than the current density at which the luminous efficiency reaches the maximum can be suppressed to a small level and the power consumption per luminance can be reduced to the minimum level as the whole display device.

Further aspects of the present invention will become apparent from the following description of exemplary embodiments with reference to the attached drawings.

### BRIEF DESCRIPTION OF THE DRAWINGS

FIG. 1 is a view illustrating the relationship between the current density and the luminous efficiency of an organic EL element of the invention.

FIG. 2 is a schematic view illustrating the cross-sectional structure of the organic EL element of the invention.

FIG. 3 is a view illustrating a drive timing chart for driving the organic EL element of the invention.

FIG. 4 is a view illustrating a cross sectional structure of the organic EL elements of an example of the invention.

### DESCRIPTION OF THE EMBODIMENTS

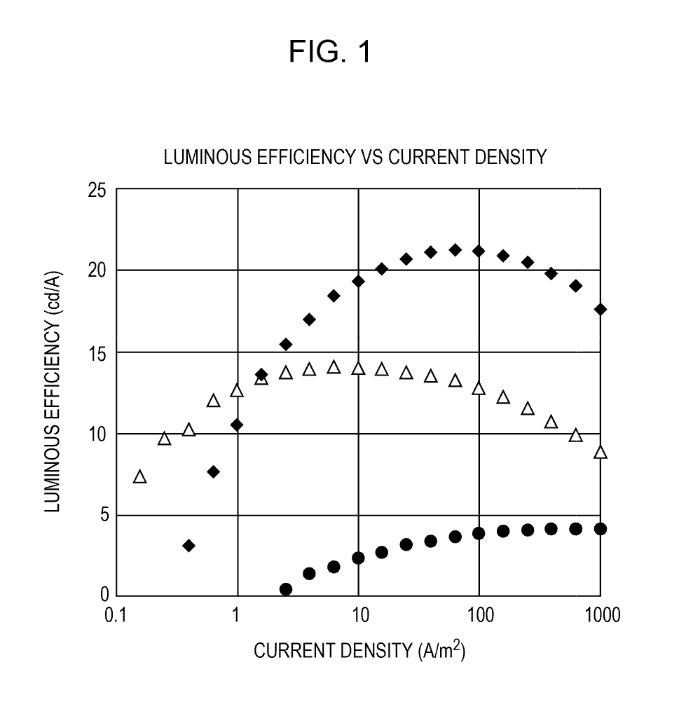

FIG. 1 is a view illustrating the relationship between the current density and the luminous efficiency of organic EL elements of R (Δ), G (♦), and B (). The horizontal axis of the logarithm scale represents the current density (A/m²) and the vertical axis of the linear scale represents the luminous efficiency (cd/A). When the current density is increased, the luminous efficiency increases with the increase in current density in low current density portions as illustrated in FIG. 1 and, after reaching the maximum value, the luminous efficiency decrease with the increase in current density.

The materials, structures, and manufacturing methods of the organic EL elements of FIG. 1 are described in detail below. R utilizes light emission by triplet excitons of phosphorescent materials and G and B use light emission by singlet excitons of fluorescent materials.

Table 1 shows the maximum luminous efficiency, the current density at which the luminous efficiency reaches the maximum, and the luminance, which is the product thereof of each organic EL element illustrated in FIG. 1. Each organic EL element has 3 colors, namely red (R), green (G), and blue (B), as sub-pixels. A wide variety of colors can be provided by varying the intensity of each of the sub-pixels, and black can be provided by turning the three sub-pixels off.

TABLE 1

| | Maximum | | |
|---|---|---|---|
| | luminous | | |
| | efficiency | Current | Luminance |
| | (cd/A) | density (A/m²) | (cd/m²) |
| R | 14.1 | 6.3 | 89 |
| G | 21.2 | 63 | 1340 |
| B | 4.1 | 396 | 1620 |

The luminous efficiency is the intensity (luminous intensity) of light emitted to the outside from the organic EL element per current flowing across the light emission surface of the organic EL element. The luminance is the intensity per unit area and thus is represented by the product of the luminous efficiency and the current density. The brightness on the display surface of an actual display device is one obtained by multiplying the luminance by the opening ratio. When there is a polarizing plate, the brightness further decreases due to the absorption thereof.

The chromaticity of each organic EL element is, on the CIExy coordinate,

### R=(0.672, 0.327),

### G=(0.220, 0.690), and

### B=(0.134, 0.084).

The luminance ratio IR:IG:IB of RGB for obtaining the standard white color D65=(0.313, 0.329) using the organic EL elements is determined as IR:IG:IB=0.285:0.607:0.108 by well-known calculation.

In contrast, in a display to be used in an ordinary room, brightness higher than a fixed value is standardized and the luminance of a screen outputting white light is usually required to be 250 cd/m² or more. When the opening ratio of RGB each is 18% and the transmittance of the polarizing plate is 45%, the total luminance of RGB on the light emission surface needs to be 250/0.18/0.45=3090, i.e., 3090 cd/m² or more. When the total luminance is distributed based on the ratio for achieving the above-described standard white color, the luminance of each color needs to be as follows: R needs to be 879 cd/m², G needs to be 1870 cd/m², and B needs to be 334 cd/m² or more.

The luminance of RGB shown in Table 1 is exceptionally different from the ratio for obtaining the standard white color and also the luminance of R with the lowest luminance under the maximum luminous efficiency conditions is absolutely insufficient for satisfying the brightness required as a display. The luminance of G is also insufficient for obtaining the white color of 250 cd/m² and thus the current density needs to increase or the opening ratio needs to increase.

As described above, when the luminance of each color is adjusted while removing the current density of each color from the conditions of the maximum luminous efficiency in order to obtain the standard white color having a given luminance, light of each color is emitted under the conditions that are quite different from the maximum luminous efficiency, and thus the power consumption becomes high.

Then, the light of the color whose luminance is insufficient relative to the brightness defined as the standard value current density is emitted while setting the current density to be higher than the current density at which the luminous efficiency reaches the maximum. The organic EL element of the color emits light with the luminance determined by the product of the set current density and the luminous efficiency at the set current density, and thus the luminance becomes higher than the luminance at the current density at which the luminous efficiency reaches the maximum. With respect to the other colors in which a sufficient luminance is obtained at the current density at which the maximum luminous efficiency reaches the maximum, the current density is set to the current density as it is and the ratio of a current supply time within unit time, i.e., duty, is adjusted. The organic EL elements emit light almost simultaneously with the start of supplying current and stop the light emission almost simultaneously with the end of supplying current. Therefore, the current supply duty is substantially the same as a light emission duty. When the duty becomes lower than 100%, the apparent luminance taking time average becomes low corresponding to the duty. The current density of the color in which the luminance is insufficient and the duty of the other colors are adjusted in such a manner as to obtain the standard white color of the brightness determined when synthesized.

In the color in which the luminance is insufficient, the current supply duty is set to the permissible highest duty higher than that of the other colors. By increasing the duty to the maximum value, an increase in the current density from the value at which the luminous efficiency reaches the maximum is suppressed to the lowest level. By emitting light of the other colors with the maximum luminous efficiency, the power consumption per luminance can be reduced to the minimum level as a whole.

The maximum duty is usually 100%. However, in a matrix display device, time for writing a data signal in each pixel is required and the supply of current stops during the period, and therefore the upper limit of the duty is sometimes lower than 100%. In this case, the duty of color which increases the current density also becomes lower than 100% and the duty of the other colors proportionally becomes small.

When all the colors of RGB have a sufficient luminance at the current density at which the luminous efficiency reaches the maximum, light may be emitted at the current density insofar as a given luminance can be maintained at the current density at which the luminous efficiency reaches the maximum. Thus, the power consumption can be reduced to the minimum level under a given luminance. However, even in such an organic EL element, the upper limit of the light emission duty is fixed. When the luminance of some colors is insufficient under the limitation of the duty, the current density of the color is made higher than the current density at which the luminous efficiency reaches the maximum and the duty thereof is set to the highest duty. With respect to the other colors, the luminance is adjusted by maintaining the current density at which the luminous efficiency reaches the maximum and making the duty lower than the maximum value.

When the luminance is in sufficient not only in color whose luminance when light is emitted at the current density at which the luminous efficiency reaches the maximum is the lowest but in color whose luminance is the second lowest, the current density of the two colors is set to be higher than the current density which gives the maximum luminous efficiency.

Hereinafter, the present invention is specifically described with reference to Examples. In the following Examples, the opening ratio is 18% equally in RGB. Although it is assumed that light emitted from the light emission surface is absorbed by a polarizing plate, it may be considered that the absorption is also included when a protective film and the like are provided. An organic EL element is described below wherein the organic EL element has the properties shown in FIG. 1 and Table 1. In the organic EL element of FIG. 1, R contains a phosphorescent luminescent material and G and B contain a fluorescent luminescent material, but the invention is not limited thereto.

### EXAMPLES

### Example 1

In this Example, the current density of each of R and G is set to be higher than a value which gives the maximum luminous efficiency and current is supplied to each of them at a duty of 100%. In B, white balance is achieved by setting the current density to the current density at which the luminous efficiency reaches the maximum and adjusting the duty.

As described above, in order to achieve a brightness on a display screen of 250 cd/m² when the standard white light is output, the luminance of R and G need to be LR=879 cd/m² and LG=1870 cd/m², respectively. In contrast, B is driven at the current density at which the luminous efficiency reaches the maximum, light is emitted at a luminance of LB=1620 cd/m² shown in Table 1. When the duty of B is set to TB %, the apparent luminance of B is LB×TB/100. In order to achieve white balance together with R and G above, the apparent luminance needs to be 334 cd/m², and thus TB=21% is achieved from LB×(TB/100)=334 cd/m².

When the current density and the luminous efficiency when the luminance of R reaches the above-described value (LR=879 cd/m²) were determined from the curve of R of FIG. 1, the current density was 67 A/m² and the luminous efficiency at the current density was 13.1 cd/A. The luminous efficiency decreased to 93% of 14.1 cd/A of the maximum luminous efficiency.

Moreover, when the current density and the luminous efficiency when G reaches the luminance of the above-described value (1870 cd/m²) were determined from the curve of G of FIG. 1, the current density and the luminous efficiency was 88 A/m² and 21.1 cd/A, respectively. The current density of G also increases from the point at which the luminous efficiency reaches the maximum but the point is near the peak, and therefore the luminous efficiency is hardly different from the maximum value.

In R and G, current is caused to flow at a duty of 100% and, in B, current is caused to flow at a duty of 21%. Therefore, the total current density taking time average is 67+88+396×0.21=235 A/m². The power consumption is obtained by multiplying the total current density by a drive voltage. When the drive voltage is 7.5 V, the power consumption is 1760 W/m² per unit area. The power consumption per luminance divided by the screen luminance of white display, 250 cd/m², is 7.04 W/cd.

The intermediate luminance between white and black, which is lower than that of white color, is obtained by modulating the magnitude of the current to be caused to flow through the organic EL element. Gradation display from 0% to 100% is obtained by modulating the current density between 0 to 67 A/m² in B, modulating the same between 0 to 88 A/m² in G, and modulating the same between 0 to 396 A/m² in R, respectively. However, in this system, B is driven at a current density lower than the current density at which the luminous efficiency reaches the maximum except display of the maximum luminance, and thus the power consumption per luminance becomes high.

By setting the magnitude of current to a fixed value and modulating the light emission time, the intermediate luminance can be output. In such a case, the duty is modulated from 0% to 100% in R and G and the duty of B is modulated between 0 to 21%. In this case, since the current density is fixed in any gradation level, the power consumption per luminance is optimally maintained similarly as in the case of outputting white color. In the driving method of the invention, it is desirable as a gradation display system that the current is fixed to the current density at which the luminous efficiency reaches the maximum and the duty is modulated.

### Example 2

This Example describes an example in which a required luminance of white light is absolutely insufficient only in R and the luminance of G and B exceeds the required luminance. A white balance is achieved by setting the current density of R to be higher than the value which gives the maximum luminous efficiency and emitting light at a duty of 100% and, in G and B, setting the current density to the current density at which the luminous efficiency reaches the maximum and adjusting the duty.

In the case where the luminance when outputting the standard white is 150 cd/m², a luminance required in the organic EL element having the properties shown in FIG. 1 and Table 1 is as follows: LR is 527 cd/m², LG is 1124 cd/m², and LB is 201 cd/m². The opening ratio and the transmittance of the polarizing plate are the same as those of Example 1.

When light of each of RGB is emitted under the conditions where the luminous efficiency reaches the maximum, the luminance is absolutely insufficient in R. Then, R is made to emit light at a current density higher than the current density at which the luminous efficiency reaches the maximum and the duty is set to 100%. G and B are made to emit light at the current density at which the luminous efficiency reaches the maximum and the duty is set to be lower than 100%.

When a current density and a luminous efficiency for obtaining LR=527 cd/m² are searched from the curve of R of FIG. 1, the current density is 39 A/m² and the luminous efficiency is 13.5 cd/A.

G and B each are made to emit light by causing a current having the current density at which the luminous efficiency reaches the maximum to flow. Therefore, the luminance of Table 1, LG=1340 cd/m² and LB=1620 cd/m², is achieved. When the duty of each of G and B is defined as TB % and TG %, respectively, in order to achieve an apparent luminance of LR=527 cd/m² and a white balance, LG×TG/100=1124 cd/m² and LB×TB/100=201 cd/m² need to achieve. Thus, TG=84% and TB=12% are achieved.

The total current density taking time average is 39+63×0.84+396×0.12=139 A/m², the power consumption per m² when the drive voltage is 7.5 V is 1040 W/m², and the power consumption when standardized by the luminance of 150 cd/m² is 6.93 W/cd.

R deviates from the maximum luminous efficiency but G and B can be made to emit light at the current density at which the luminous efficiency reaches the maximum. Therefore, the power consumption per luminance becomes further lower than that of Example 1.

### Comparative Example

For comparison, a case where the duty of not only R and G but B is set to 100% in Example 1 is described below.

Since B outputs at a duty of 100% and a luminance of 334 cd/m², light is emitted at a current density of 85 A/m² and a luminous efficiency of 3.9 cd/A, which deviate from the point at which the luminous efficiency reaches the maximum. The luminous efficiency decreases to 95% of the maximum value. The total current density is 67+88+85=240 A/m². The power consumption at a drive voltage of 7.5 V is 1800 W per m². The power consumption per luminance is 7.2 W/cd and is higher than that of Example 1 and 2.

When the duty of all of the RGB is set to 50%, the luminance for displaying white color with a total luminance of 250 cd/m² is twice the luminance mentioned above and the current density and the luminous efficiency for obtaining the luminance are as follows:

R: Current density of 146 A/m² and Luminous efficiency of 10.9 cd/A,
G: Current density of 177 A/m² and Luminous efficiency of 20.8 cd/A,
B: Current density of 201 A/m² and Luminous efficiency of 4.0 cd/A. The luminous efficiency of each of them decreases to 77%: 98.1%: 97.5% relative to the maximum value.

The total current density is (146+177+201)×0.5=262 A/m². The power consumption when the drive voltage is 7.5 V is 1970 W per m2 and is further higher than that in the case where the duty is all set to 100%.

### <Drive Circuit>

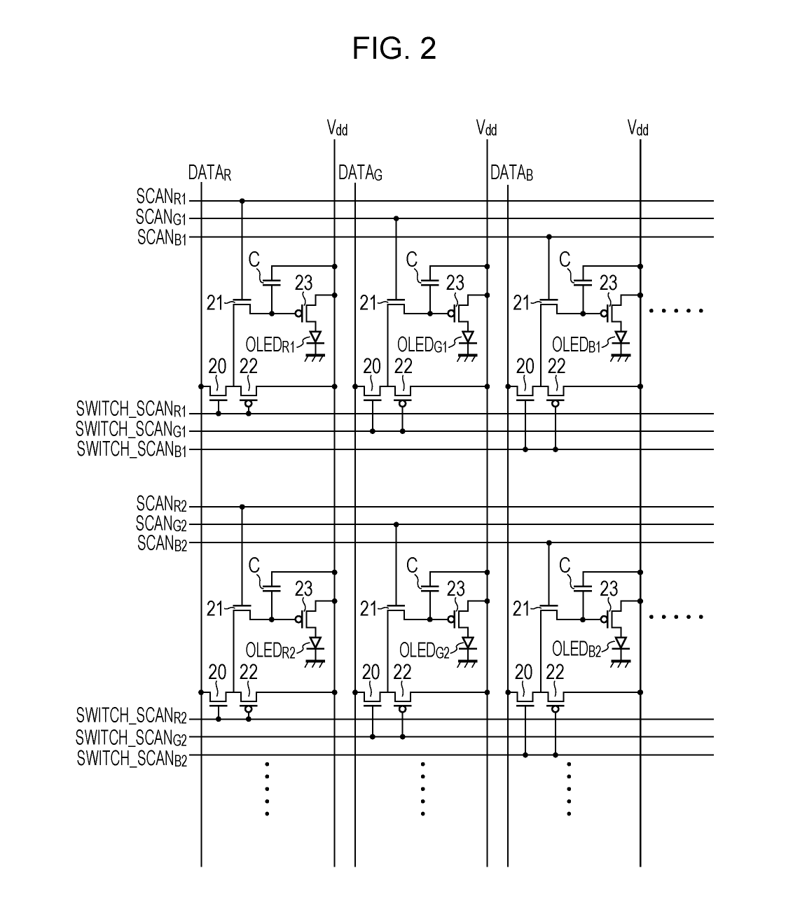

In order to vary the light emission duty among the organic EL elements of different colors, a drive circuit capable of controlling the light emission time needs to use. FIG. 2 is one example of a circuit therefor and is an enlarged circuit diagram in which the organic EL display device is partially enlarged. In the row direction, organic EL elements of RGB, OLED_{R}, OLED_{G}, and OLED_{B}, are periodically disposed. In the column direction, the organic EL elements of the same color are disposed.

Each organic EL element OLED is connected to a drive circuit containing transistors 20 to 23 and a capacitor C, and is driven. In each row, scanning lines SCAN_{Ri}, SCAN_{Gi}, and SCAN_{Bi} and erasing scanning lines SWITCH_SCAN_{Ri}, SWITCH_SCAN_{Gi}, and SWITCH_SCAN_{Bi} are disposed. i is a subscript that represents the row number.

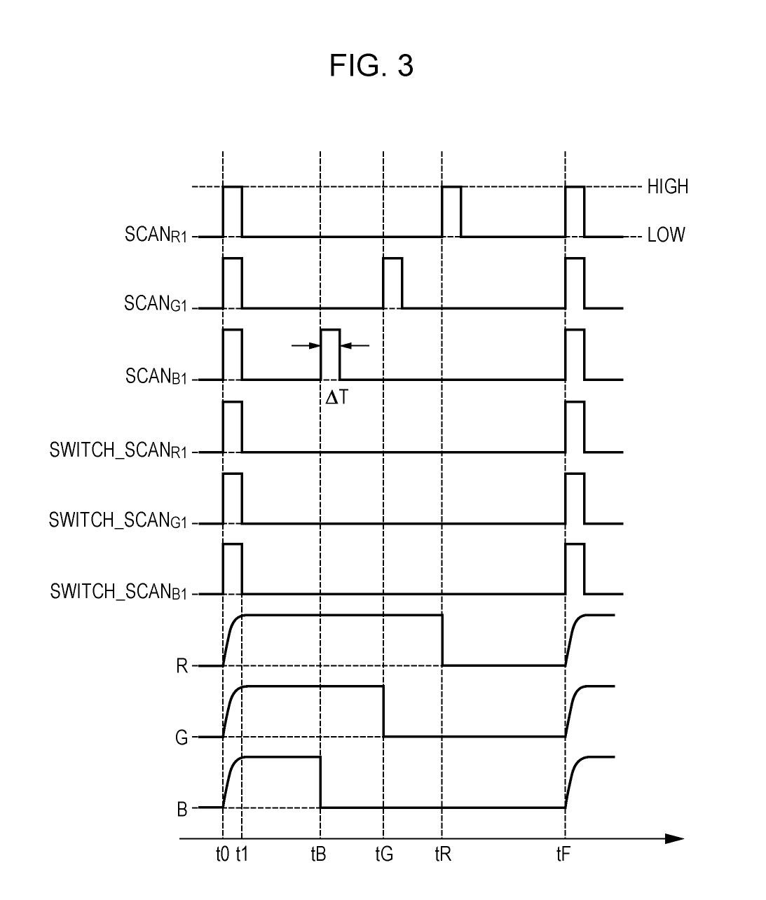

FIG. 3 illustrates a drive timing chart of the circuit of FIG. 2. FIG. 3 represents each signal of the scanning lines SCAN and the erasing lines SWITCH_SCAN of one row during one frame period t0 to tF and R, G, and B of the timing of light emission of the organic EL elements OLED.

During t0 to t1, writing of data is performed. The scanning lines SCAN and the erasing lines SWITCH_SCAN of RGB are all set to HIGH (hereinafter, the subscript representing the color and the subscript representing the row number are omitted). The transistors 20 and the transistors 21 are electrically connected, the gates of the transistors 23 of the row are connected to DATA lines, a current flows between the sauce and the drain of the drive transistors 23, the current is supplied to the OLEDs, and the OLEDs emit light.

Thereafter, the scanning lines SCAN and the erasing scanning lines SWITCH_SCAN are all set to LOW at t1, but the gate voltage of the transistors 23 are held at a retention volume C, so that the light emission continues.

The periods from tR, tG, and tB to ΔT each are periods in which the data of R, G, and B are erased and the light is switched off. During the data erasing, the SWITCH_SCAN lines are in LOW and the scanning lines SCAN are set to HIGH, the gates of the transistor 23 are connected to VDD lines, the transistors 23 are switched OFF, and the light emission ends. Since the electric discharge of the retention volume C is simultaneously performed, the light is switched OFF thereafter.

By adjusting the data erase timings tR, tG, and tB, the light emission time of RGB can be controlled.

### Manufacturing Method

A method for manufacturing the organic EL element of Example 1 is described below.

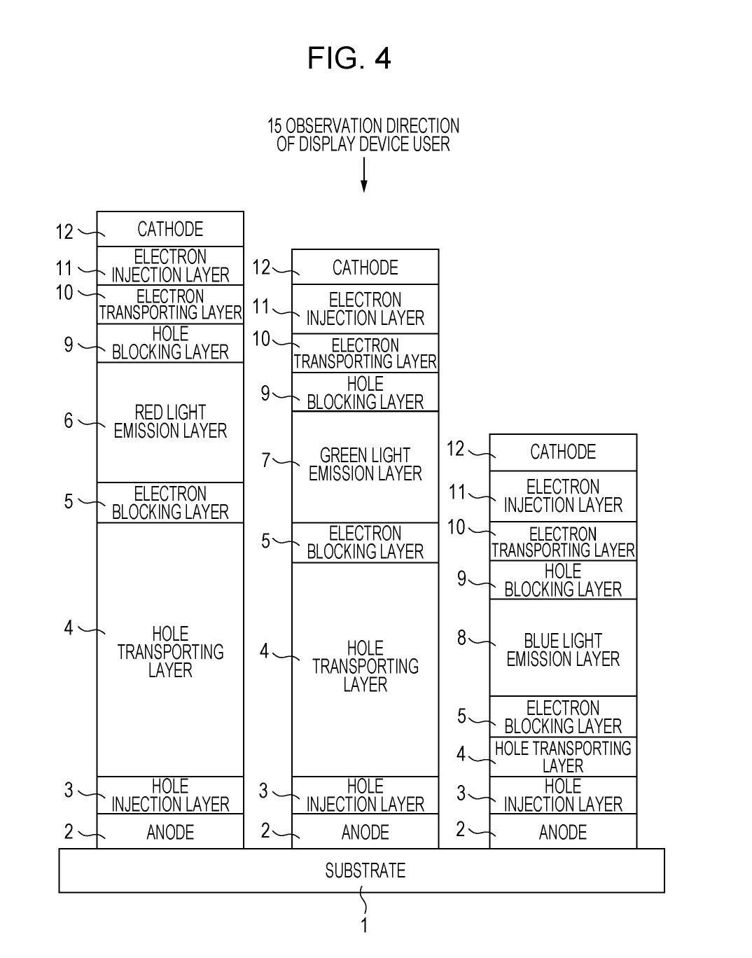

FIG. 4 is a view illustrating the cross sectional structure of the organic EL elements of Example 1. Pixels are constituted by top-emission organic EL elements containing 3 colors of RGB. An anode is located at the side of a substrate and a cathode is located at the side of light extraction.

On a substrate 1 on which a TFT was formed, a planarization film having a contact hole was formed (the TFT, the planarization film, and the contact hole are not illustrated). Next, by a sputtering method, a 100 nm Ag alloy film was formed, and then a 10 nm indium oxide tin (ITO) film was laminated thereon. Then, by patterning the laminate, an anode 2 was formed (In FIG. 2, the Ag alloy film and the ITO film are combined to be indicated as the anode 2). The anode 2 is connected to the TFT through the contact hole. The Ag alloy film is the anode and also functions as a reflection surface. Next, an element isolation film (not illustrated) was produced using a lithography technology to an insulating layer formed on the anode 2. The element isolation film is provided for isolating pixels and sub-pixels to independently drive the same by the TFT.

Next, pretreatment of the substrate is described. The substrate was baked at 100° C. for 5 minutes in a vacuum, subjected to UV ozone cleaning in the dry air, and then re-baked at 100° C. for 10 minutes in a vacuum.

After the completion of the pretreatment, a metal mask was aligned with the substrate, and painting in different colors was performed with a required film thickness, thereby forming an organic layer.

A hole injection layer 3 and an electron blocking layer 5 of RG pixels are not sometimes formed.

The hole transporting layers were formed with a diamine compound in such a manner as to be 230 nm in an R pixel, 160 nm in a G pixel, and 90 nm in a B pixel.

Next, monoamine was vapor deposited with 10 nm as the electron blocking layer 5 only to the B pixel.

The following organic materials were co-vapor deposited with 40 nm to form a G light emission layer 7. 10 vol % of a green light emission dopant GD12 and an assistant dopant GD9 represented by the following structural formulae (G) are contained.

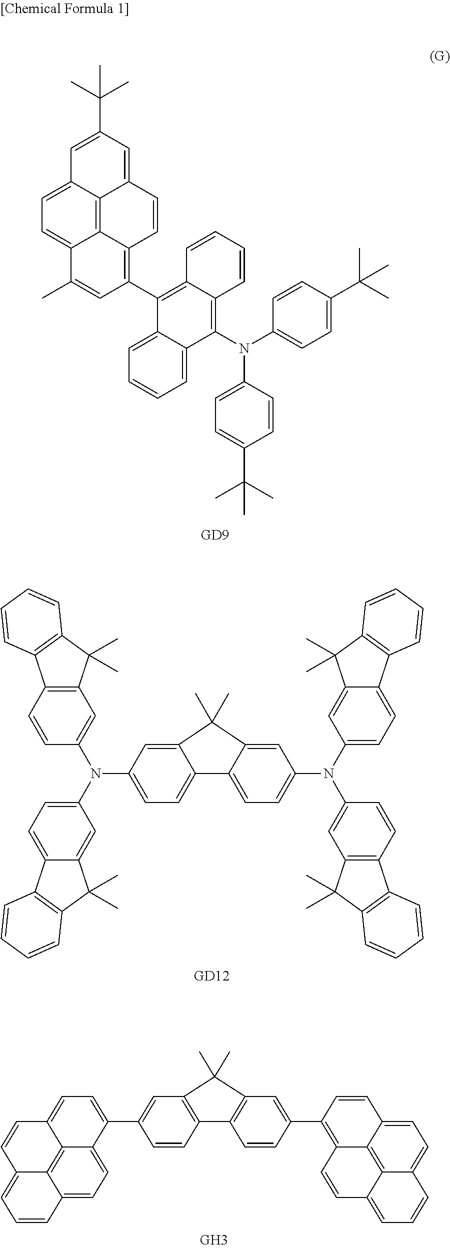

30 nm of the following organic materials were co-vapor deposited to form an R light emission layer 6. 2 vol % of a red light emission dopant RD9 and 15 vol % of assistant dopant RD12 represented by the following structural formulae (R) are contained. RD9 and RD12 are phosphorescent materials.

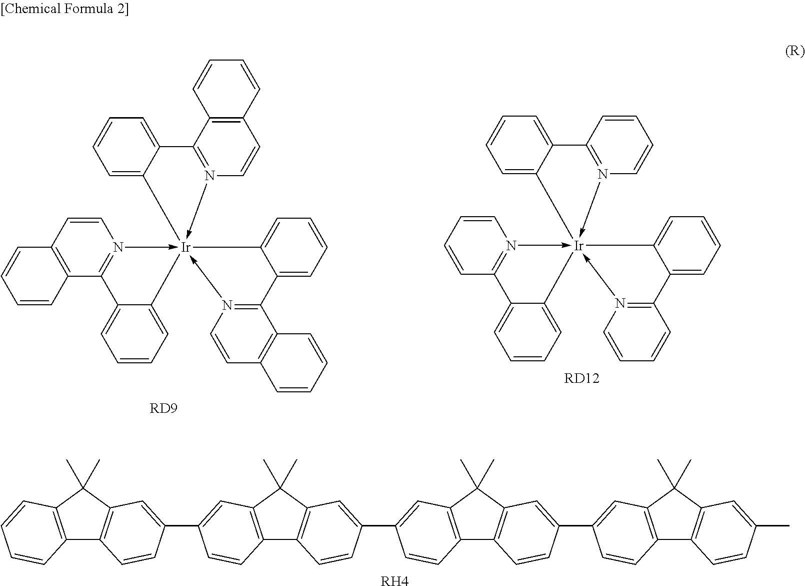

The following organic materials were co-vapor deposited with 35 nm to form a B light emission layer 8. The organic EL material of B contains 2 vol % of blue light emission dopant BD12 represented by the following formula (B).

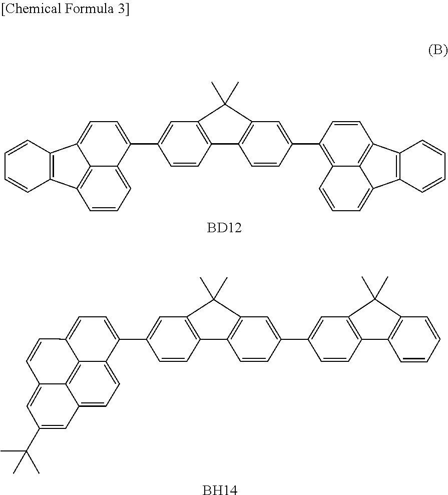

The following layers are common to RGB.

A hole blocking layer 9 was formed using a fluorene compound with a film thickness of 10 nm. Next, a phenanthroline compound was formed with a film thickness of 10 nm as an electron transporting layer 10.

After forming the electron transporting layer 10, the phenanthroline compound and cesium carbonate were formed into a film in such a manner that the film thickness of the co-vapor deposited film was 60 nm by adjusting a vapor deposition rate in such a manner that the cesium concentration was 23 wt %, thereby forming an electron injection layer 11.

A cathode 12 was formed by 60 nm sputtering indium zinc oxide (IZO). The upper interface of IZO serves as a reflection surface utilizing a refractive-index difference, and forms a microcavity structure with a reflection film at the anode side.

Finally, ultraviolet curing resin is applied to the periphery of the substrate 1 under an N2 atmosphere, a glass substrate is pasted thereto, and then ultraviolet rays are irradiated for sealing. In this process, pixel portions were masked so that ultraviolet rays are not applied thereto.

The present invention is not limited to the organic EL element having the structure illustrated in FIG. 4 and can be applied to an organic EL display device in which the luminous efficiency to the current density has the maximum peak. The organic EL materials for use in the invention may be either fluorescent materials or phosphorescent materials. When an organic EL element of at least one color contains phosphorescent materials and the current density at which the luminous efficiency thereof reaches the maximum is lower than that of organic EL elements containing other fluorescent materials, the invention is suitably applied.

The invention is not limited to a display device employing a top-emission organic EL element and can also be applied to a display device employing an organic EL display element, such as a bottom-emission EL display element or a double-sided light emission EL display element. An organic EL element in which the anode is closer to the substrate relative to the cathode and a drive TFT (not illustrated) is connected to the anode may be acceptable or the reverse arrangement may be acceptable.

The invention is not limited to an organic EL display device in which one pixel is constituted by RGB and can also be applied to an organic EL display device in which two or more sub-pixels of the same color are contained per pixel, such as RGBB.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-169701 filed Jul. 28, 2010, which is hereby incorporated by reference herein in its entirety.

What is claimed is:

1. A light emitting device comprising organic EL elements of different colors and outputting light emitted from the organic EL elements,
wherein
the luminance of the organic EL element of one color is lower than that of the organic EL elements of the other colors when each of the organic EL elements of different colors emits light by a supplied current of a current density at which a luminous efficiency reaches a maximum,
and
when the light emitting device outputs white light, the organic EL element of the one color emits light by a supplied current of a current density higher than the current density at which the luminous efficiency reaches the maximum at a highest duty among the organic EL elements of different colors, and the organic EL elements of the other colors emit light by supplied currents of the current density at which the luminous efficiency reaches the maximum.

2. The light emitting device according to claim 1, wherein the highest duty in the organic EL elements of different colors is lower than 100%.

3. The light emitting device according to claim 1, wherein, when the light emitting device outputs light having a luminance lower than that of the white light, a current equal to the current supplied when outputting white light is supplied to each of the organic EL elements of different colors, and each of the organic EL elements of different colors emits light by a current equal to the current supplied when the light emitting device outputs light at a duty lower than the duty when the light emitting device outputs white light.

4. The light emitting device according to claim 1, wherein the organic EL element of the one color includes a phosphorescent material in a light emission layer.

5. The light emitting device according to claim 1, wherein the organic EL elements of different colors are organic EL elements each having 3 colors, namely red, green, and blue, as subpixels.

6. The light emitting device according to claim 1, wherein the light emitting device is a display device.

7. The light emitting device according to claim 1, wherein the light emitting device is a lighting device.

8. A method for driving a light emitting device containing organic EL elements of different colors, the method comprising:
when outputting white light,
supplying to the organic EL element of one color a current of a current density higher than a current density at which a luminous efficiency reaches a maximum at a highest duty among the organic EL elements of different colors, and
supplying to the organic EL elements of the other colors currents of the current density at which the luminous efficiency reaches the maximum.
